(19) United States
(12) Patent Application Publication
(10) Pub. No.: US 2004/0084757 A1
(43) Pub. Date: May 6, 2004

(54) Micro leadframe package having oblique etching

(75) Inventor: Dae Sung Seo, Seoul (KR)

Correspondence Address: ROTHWELL, FIGG, ERNST & MANBECK, P.C., 1425 K STREET, N.W., SUITE 800, WASHINGTON, DC, 20005, US

(73) Assignee: SIGNETICS KOREA CO., LTD., Paju-city (KR)

(21) Appl. No.: 10/694,955

(22) Filed: Oct. 29, 2003

(30) Foreign Application Priority Data
Oct. 29, 2002 (KR) 2002-66122

(51) Int. Cl. H01L 23/495

(52) U.S. Cl. 257/672

(57) ABSTRACT

A micro leadframe package employing an oblique etching method is disclosed. The micro leadframe package includes a semiconductor chip, an oblique-etched micro leadframe (MLF) having a die pad on which the semiconductor chip is mounted via adhesive means, leads formed along outer sides of the die pad, and tie bars for supporting four corners of the die pad, wires for connecting the semiconductor chip with the leads of the MLF, and an epoxy molding compound (EMC) for encapsulating the semiconductor chip, the MLF, and the wires.

### BACKGROUND OF THE INVENTION

This application claims the priority of Korean Patent Application No. 2002-66122, filed on Oct. 29, 2002, in the Korean Intellectual Property Office, the disclosure of which is incorporated herein in its entirety by reference.

1. Field of the Invention

The present invention relates to a semiconductor package, and more particularly, to a micro leadframe package (hereinafter referred to as an MLP).

2. Description of the Related Art

Recently, the size of small electronic devices, such as cellular phones, digital cameras, digital camcorders, and notebook computers, are rapidly becoming increasingly compact. Further, as the integration density of semiconductor chips increases, the size of the semiconductor chips becomes smaller. As a result, the size of semiconductor packages has been much smaller in comparison to conventional semiconductor packages. Thus, a ball grid array (BGA) package and a micro leadframe (MLF) package, etc. have been developed. They are attached to a printed circuit board (PCB) for a small electronic device, resulting in an increase in the mounting density of semiconductor devices.

FIG. 1 is a plan view of an MLP 10 according to prior art, FIG. 2 is a side view of an MLP 10 according to prior art, and FIG. 3 is a bottom view of an MLP 10 according to prior art.

Referring to FIGS. 1 through 3, the MLP 10 is generally constructed so that leads 14 are formed inside a package body consisting of an epoxy molding compound (EMC) 12, thereby reducing its size. The MLP 10 has a die pad 16 formed and exposed at and outward from a bottom surface thereof and a solder is attached to the exposed die pad 16 when the MLP 10 is mounted on a PCB, so that heat dissipation capability of the MLP 10 increases.

Generally, since the MLP has the depth of about 0.2 mm and is very thin, its shape is formed using an etching method. However, in a case where a bottom surface of the thin MLF is exposed in a state not encapsulated by an EMC, attachment strength between the EMC and the MLF 30 after a molding process, that is, molderability is reduced. In order to prevent the above problem, the pattern of the MLF is formed using a half-etching method.

However, the conventional MLP has the following problems.

First, since the reduction in size of the MLP is continuously demanded, the depth of the MLF is expected to be reduced to 0.15 mm or less in advance. However, at least 0.1 cm from the bottom surface of the MLF must be etched in the half-etching method in order to fill the EMC. Thus, in order to meet the above-described conditions, a very difficult process is required to manufacture the MLF, thus the rate of defects to occur increases. Therefore, the cost of the MLF increases, resulting in an increase in the cost of the MLP.

For reference, the reason for the difficulty in the half-etching process used when manufacturing the MLF is as follows. When an etching solution is injected into an upper surface and a bottom surface of the MLF to perform half-etching, the etching solution and the half-etching method used in the upper surface are different from those used in the bottom surface. Thus, the half-etching process is difficult, thereby causing the increase in the rate of defects.

Secondly, in a case where the MLP is mounted on the PCB using the solder, the attachment strength between the MLP and the PCB is reduced because the solder exists on only the bottom surface of the MLP. That is, the solderbility is deteriorated, and thus the reliability of the MLP is reduced.

### SUMMARY OF THE INVENTION

The present invention provides an inexpensive and reliable micro leadframe package by improving the structure of a micro leadframe.

According to an aspect of the present invention, there is provided a micro leadframe package. The micro leadframe package comprises a semiconductor chip; a micro leadframe (MLF) having a die pad on which the semiconductor chip is mounted via adhesive means, leads formed along outer sides of the die pad, and tie bars for supporting four corners of the die pad, wires for connecting the semiconductor chip with the leads of the MLF; and an epoxy molding compound (EMC) for encapsulating the semiconductor chip, the MLF, and the wires. Here, the die pad, the leads, and the tie bars have an oblique etching portion.

It is preferable that dimples are formed on the die pad, leads, and tie bars of the MLF for increasing the attachment strength between the micro leadframe package and the EMC. Further, a plurality of dimples are formed along four edges of the die pad.

It is preferable that holes for firm solder connection are formed at the tips of the leads which are encapsulated by the EMC and the diameter of the holes for firm solder connection ranges from 50% to 95% of the width of the leads.

It is preferable that the size of a bottom surface of the MLF is greater than that of an upper surface in an oblique etching method used in the MLF, and the size of the bottom surface of the MLF is greater than that of the upper surface by about 1-10%.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a micro leadframe package (MLP) according to prior art;

FIG. 2 is a side view of an MLP according to prior art;

FIG. 3 is a bottom view of an MLP according to prior art;

FIG. 4 is a plan view of an MLF according to the present invention;

FIG. 5 is a cross-sectional view taken along lines IV-IV′ of FIG. 4;

FIG. 6 is a plan view of an MLP according to the present invention;

FIG. 7 is a side view of an MLP according to the present invention;

FIG. 8 is a bottom view of an MLP according to the present invention; and

FIG. 9 is a cross-sectional view of an MLP according to the present invention.

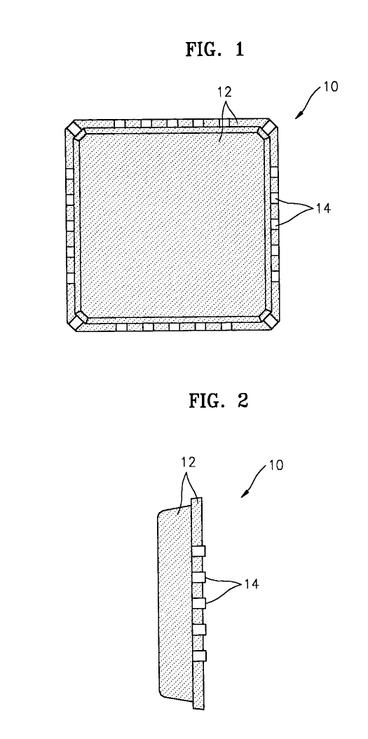

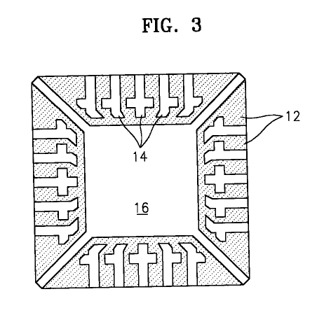

### DETAILED DESCRIPTION OF THE INVENTION

The term “micro leadframe (MLF)” referred in the specification should not be construed as being limited to the embodiments set forth herein. The present invention may be embodied in many different forms within the spirit and scope of the invention as defined by the claims. For example, although a dimple is formed at an edge of a die pad in the preferable embodiments, the position of the dimple may be changed. Accordingly, the preferable embodiments to be described below are regarded in an illustrative rather than restrictive sense.

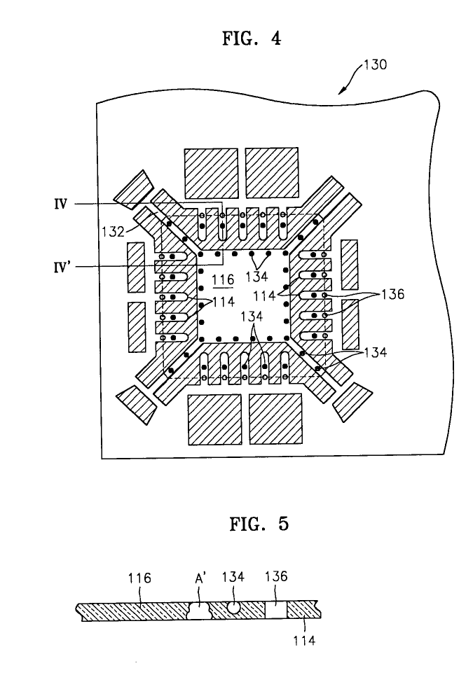

FIG. 4 is a plan view of an MLF 130 according to the present invention and FIG. 5 is an etching cross-sectional view taken along lines IV-IV′ of FIG. 4.

Referring to FIGS. 4 and 5, the MLF 130 includes a die pad 116 on which a semiconductor chip is mounted, leads 114 formed along outer sides of the die pad 116, and tie bars 132 for supporting four corners of the die pad 116. The MLF 130 is formed not by a half-etching method used in the conventional MLF or a vertical-etching method used in a general etched leadframe but an oblique etching method as indicated by a reference character A′ of FIG. 5.

Here, the oblique etching method proceeds as follows. First, a photoresist is coated on upper and lower surfaces of a leadframe member, and then, an etching solution is injected therein, thereby obtaining an oblique etched MLF pattern. Here, the size of the oblique etched pattern of the bottom surface of the MLF is lightly greater than that of the oblique etched pattern of the upper surface. In the oblique etching method, attachment strength in an up-and-down direction between the MLF and an EMC is improved, compared to the general etched leadframe which is etched in a vertical direction. Further, in the MLF using the existing half-etching method, in order to make the MLF into an elaborate shape, an etching solution or an etching method used in the upper surface of the MLF must be different from those used in the bottom surface. However, the above-described difficult process of the existing half-etching method is not required in the oblique etching method. That is, the oblique etching method can be performed using simple processes, which is applied in the vertical-etching method. Thus, the manufacturing cost of the MLF formed using the oblique etching method is more inexpensive than that of the MLF formed using the half-etching method, and the yield of the MLF becomes higher. Preferably, the size of the oblique etching portion in the bottom surface of the MLF is greater than that of the upper surface by about 1-10%. The oblique etching portion in the bottom surface may greater beyond the above range, as needed.

However, an attachment strength between the MLF 130 manufactured by the oblique etching method and the EMC is less than that between the MLF manufactured by the half-etching method and the EMC. In order to supplement the above problem, the MLF 130 according to the present invention has dimples 134 formed at the leads 114, four edges of the die pad 116, and the tie bars 132. The dimples 134 prevent the die pad 116 and the leads 114 from failing outward due to the weak attachment strength after molding.

Further, the MLF 130 has holders 136 for firm solder connection formed at the tips of the leads 114 to be cut. Generally, an MLP using the MLF 130 is manufactured by the following processes, that is a die attach process, a wire bonding process, a molding process, an electroplating process of the exposed MLF 130, and a cutting process.

Thus, a solder is plated inside the holes 136 for firm solder connection during the electroplating process. When the MLP is mounted on the PCB, the plated solder is melted onto the sidewalls of the MLP to be attached to the PCB, thereby improving the solderbility. That is, since the holes 136 for firm solder connection are not formed at the tips of the leads 114 of the conventional MLF, a solder is not plated at the tips of the leads 114 during the electroplating process. However, according to the present invention, since the holes 136 for firm solder connection are formed at the lead tips is maintained during the sequential cutting process. Thus, when the MLP is mounted on the PCB, the solder remaining at the lead tips is melted in the MLP to be attached to the PCB, as a result of the attachment strength between the MLP and the PCB, that is, the solderbility increases.

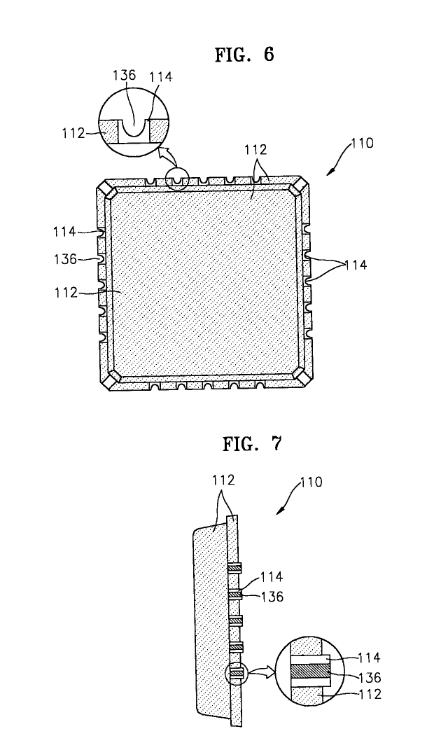

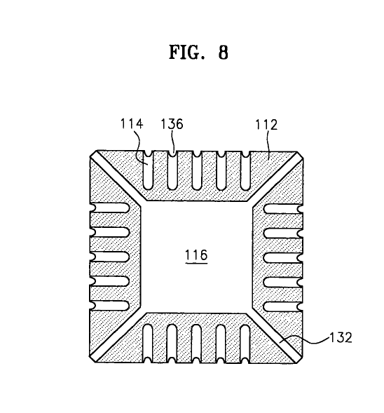

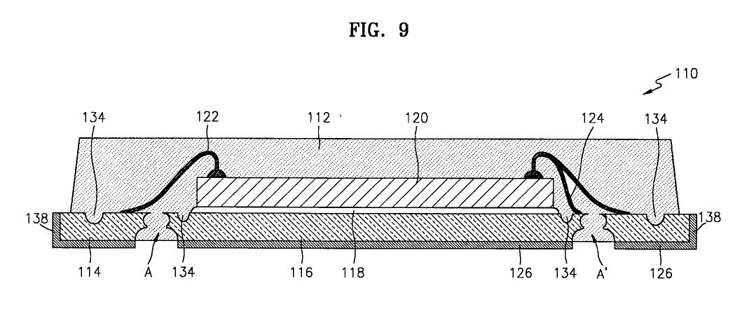

FIG. 6 is a plan view of an MLP 110 according to the present invention, FIG. 7 is a side view of the MLP 110 according to the present invention, and FIG. 8 is bottom view of the MLP 110 according to the present invention.

Referring to FIGS. 6 through 8, the MLP 110 is characterized in that grooves having a semicircle shape are formed at the tips of the leads 114. The semicircle shape grooves are formed by cutting holes 136 for firm solder connection during the cutting process. Since the solder is plated in the semicircle shape grooves, the semicircle shape grooves function to increase the attachment strength between the MLP 110 and the PCB, that is, the solderbility when the MLP 110 is mounted on the PCB. It is preferable that the diameter of the holes 136 for firm solder connection ranges from 50% to 95% of the width of the leads 114.

FIG. 9 is a cross-sectional view of an MLP 110 according to the present invention.

The MLP 110 includes an MLF having a die pad 116 on which a semiconductor chip 120 is mounted, leads 114 formed along outer sides of the die pad 116, and tie bars 132 for supporting four corners of the die pad 116. Here, the die pad 116, the leads 114, and tie bars 132 are oblique-etched as described above. A plurality of dimples 134 are formed on the leads 114, four edges of the die pad 116, and the tie bars 132 to improve the attachment strength between the MLF and an EMC 120. The semiconductor chip 120 is mounted on the die pad 116 of the MLF via adhesive means 118. The semiconductor chi 120 is connected electrically to the leads 114 through wires 122. A reference numeral 124 represents a ground bonding wire for directly connecting the semiconductor chip 120 to the die pad 116. The semiconductor chip 120, the wires 122 and 124, and the MLF, except a bottom surface thereof, are encapsulated by an EMC 120. A solder 126 is plated in the exposed leads 114 and the exposed bottom surface of the die pad 116, and a solder 138 is plated in side surfaces of the leads 114 using holes for firm solder connection (refer to the reference number 136 of FIG. 6). Thus, when the MLP 110 is mounted on the PCB, the attachment strength between the MLP 110 and the PCB increases.

As described above, the preset invention has the following advantages.

First, the cost of an MLF can be reduced, and thus, the cost of an MLP can be reduced.

Second, attachment strength between a surface of the MLF and an EMC can increase due to dimples formed at leads, tie bars, and a die pad of the MLF.

Third, when the MLP is mounted on a PCB, the attachment strength between the MLP and the PCB can increase using holes for firm solder connection formed at the tips of the leads.

While the present invention has been particularly shown and described with reference to preferred embodiments thereof, it will be understood by those of ordinary skill in the art that various changes in form and details may be made therein without departing from the spirit and scope of the present invention as defined by the appended claims.

What is claimed is:

1. A micro leadframe package comprising:
a semiconductor chip;
a micro leadframe (MLF) having a die pad on which the semiconductor chip is mounted via adhesive means, leads formed along the outer sides of the die pad, and tie bars for supporting four corners of the die pad wherein the die pad, the leads, and the tie bars have an oblique etching portion;
wires for connecting the semiconductor chip with the leads of the MLF; and
an epoxy molding compound (EMC) for encapsulating the semiconductor chip, the MLF, and the wires.

2. The micro leadframe package of claim 1, wherein a dimple is formed on the die pad of the MLF for increasing the attachment strength between the micro leadframe package and the EMC.

3. The micro leadframe package of claim 2, wherein the plurality of dimples are formed along four edges of the die pad.

4. The micro leadframe package of claim 1, wherein dimples are formed on the leads of the MLF for increasing the attachment strength between the micro leadframe package and the EMC.

5. The micro leadframe package of claim 1, wherein dimples are formed on the tie bars of the MLF for increasing the attachment strength between the micro leadframe package and the EMC.

6. The micro leadframe package of claim 1, wherein holes for firm solder connection are formed at the tips of the leads which are encapsulated by the EMC.

7. The micro leadframe package of claim 6, wherein the diameter of the holes for firm solder connection ranges from 50% to 95% of the width of the leads.

8. The micro leadframe package of claim 1, wherein the size of the oblique etching portion in a bottom surface of the MLF is greater than that of an upper surface.

9. The micro leadframe package of claim 8, wherein the size of the oblique etching portion in the bottom surface of the MLF is greater than that of the upper surface by about 1-10%.

10. The micro leadframe package of claim 1, wherein the die pad, the leads, and the tie bars are coplanar after being encapsulated by the EMC, and are exposed outward.

11. The micro leadframe package of claim 1, wherein an etching solution and an etching method used on the upper surface of the MLF are the same as those used on the bottom surface.
